(19) United States
(12) Patent Application Publication
(10) Pub. No.: US 2003/0070827 A1
(43) Pub. Date: Apr. 17, 2003

(54) HF-shielded module chassis

(76) Inventors: Elmar Daub, Pfinztal (DE); Achim Fauth, Straubenhardt (DE)

Correspondence Address: SCHWEGMAN, LUNDBERG, WOESSNER & KLUTH, P.A., P.O. BOX 2938, MINNEAPOLIS, MN, 55402, US

(21) Appl. No.: 10/266,034

(22) Filed: Oct. 7, 2002

(30) Foreign Application Priority Data
Oct. 8, 2001 (DE) 101 49 445.9

(51) Int. Cl. H05K 9/00

(52) U.S. Cl. 174/35 R

(57) ABSTRACT

An HF-shielded module chassis for the reception of electronic and/or optical modules consisting of two side walls, front and rear module bars that are arranged between the side walls and an upper cover and a lower cover. The upper and lower covers include a honeycomb screen and a surrounding frame of metal that is electrically conductive connected with the honeycomb screen. The front and rear module bars each form the front and rear frame strips of the frame. The two lateral frame strips of the frame have means for the mounting on the side walls.

### RELATED APPLICATION

This application claims priority under 35 U.S.C. 119 from German Application No. 101 49 445.9, filed Oct. 8, 2001, which application is incorporated herein by reference.

### BACKGROUND

The invention concerns a HF-shielded module chassis for the reception of electronic and/or optical modules, with two side walls, front and rear module bars that are located between the side walls, and an upper and a lower cover.

The invention is used with module chassis that are required to have a very high shielding effect against outside electromagnetic influences, or in which modules are inserted that generate electromagnetic interferences that are not allowed to get into the surroundings.

High-frequency tight module chassis and suitable means or methods for the shielding are known. The shielding of a module chassis that is assembled from a frame with four module bars and two side walls customarily consist of the side walls itself, a rear panel, a front panel and metallic covers on top and on the bottom. The quality of the shielding effect of such a closed case depends on one hand on the quality of the electrical contact between the enclosing components, and on the other hand on the size and number of openings that are inserted in the case of the module chassis for the purpose of ventilation.

A good electrical bonding of the individual components is achieved by the use of fastening screws that are located close to each other, or with the help of electrically conductive seals or spring elements. Special difficulties arise from the grooves between the case and the respective cover or shielding elements that frequently have to be removed for the purpose of maintenance while the shielding effect is not allowed to deteriorate after repeated removal and insertion.

A shielded module chassis of the previously described kind is known from the applicant's patent letter DE 42 23 322 C1. The case described therein assures a high-frequency tight bonding between a removable cover and the upper module bars of a module chassis with specially designed spring elements that are clamped in longitudinal grooves of the upper module bars, in which rounded-off small edge strips of the cover can be clamped in as well. The HF-shielding is therefore relatively consuming generated with additional components.

Another module chassis that consists of a frame with four cross-link bars and two screwed-on side walls is known from the publication WO 00/21348. Besides the two side parts, the module chassis described therein is embraced by a front panel, a rear panel, a bottom and an upper cover. The individual components are screwed together with the cross-link bars, so that a good electrically conductive contact exists. The shielding effect of the module chassis is improved in such a way that the cover parts and the cross-link bars are designed in one piece. That avoids the appearance of joints between the cover sheet metal and the connection bars which must later be sealed against high frequency.

The known module chassis' have in common that the components used for the cover are designed as sheet metals which have a good shielding effect by itself. This creates completely, or nearly completely, closed module chassis that are either not at all or only insufficiently ventilated. It is difficult to carry off heat to the outside that is generated in the module chassis.

The advancing technology leads to ever-increasing packing density of modules within the module chassis and to ever-increasing clock rates that can especially be found in equipment in the computer sector and in the mobile telephone sector, such as in UMTS applications. The result is that more and more heat is generated within the module chassis. An increase in power input of the individual components of the modules results in an increased heat dissipation as well. The cooling of the installed electronic device can only be achieved if sufficient air can flow through the module chassis. For that purpose, holes or openings are inserted in the sheet metal which basically counteracts the HF-shielding.

To prevent the shield effect even for high frequency from getting lost through the openings, only small holes can be used for the perforation of the sheet metal. In the practical application, the diameter of the holes is limited to a maximum of 4 mm, so that even high-frequency electromagnetic interference fields in gigahertz range can be shielded sufficiently. Usually the holes are punched out of the closed sheet metal afterwards. This can technically be realized only if sufficiently wide ties remain between adjacent holes. But this also results in an unfavorable relation between the created hole area and the remaining ties. The perforation degree of the sheet metal, meaning the relation of total opening area of all openings to the total area of the sheet metal, is relatively small. The air flow through the sheet metal and therefore the cooling of the electronic device that is installed in the module chassis is for that reason extremely limited. An improvement of the ventilation could only be created by the use of larger holes, but that would have a negative effect on the shielding effect of the module chassis.

It is therefore the task of the invention to create a HF-shielded module chassis of the previously mentioned kind which enables a maximal ventilation of the internal components with excellent shielding effect at the same time.

### SUMMARY

The present invention is an HF-shielded module chassis having two side walls, front and rear module bars that are arranged between the side walls, and an upper cover and a lower cover. The task is solved according to the invention in such a way that the covers consist of a honeycomb screen and a surrounding frame made of metal, so that the frame is conductively connected with the honeycomb screen, that the front and rear module bars each form the front and rear frame strips and that the lateral frame strips have means for mounting on the side walls.

The insertion of a honeycomb screen as cover offers a maximum flow through the module chassis. The honeycomb screen has a very high perforation degree due to the favorable relation of its openings to the very narrow ties between the individual honeycombs. The air can practically flow undisturbed from below to the top through the honeycomb screen. Despite the low flow resistance the honeycomb screen possesses an excellent shielding effect, because the individual honeycombs represent short waveguides in which high frequency electromagnetic waves are heavily damped.

The frame surrounding the honeycomb screen increases the intrinsic rigidity and the stability of the honeycomb screen so that no further supporting elements are needed; the total area of the cover can therefore be used as honeycomb screen. On the other hand, the frame grades the edge of the honeycomb screen which is formed jagged due to the geometry of its honeycomb structure. The framing allows the honeycomb screen to be fitted without problems into the right-angled structures of the module chassis.

The front and rear module bars are, according to the invention, part of the frame which maximizes the area formed as the honeycomb screen. An extensive HF-tight bonding between the frame and the module bars does not apply. The use of common shield seals or spring elements to bridge the grooves between the frame and the module bars can be eliminated. Additionally, the honeycomb screen becomes part of the supporting structure of the module chassis through the integration of the module bars, thereby increasing stability.

The provisions intended on the lateral frame strips to mount the honeycomb screen to the side walls allow to minimize the parallel to the side wall appearing groove between the sidewall itself and the frame strips. With the use of several mounting devices the groove is shortened so extremely that it represents a tight connection for high frequencies as well.

In a preferred variation, the lateral frame strips are screwed together with the side walls. The screws can be tightened with optimal torque by which the frame strip is ideally positioned on the side wall and the slot or groove width is minimized. Furthermore, the screws can be loosened again to change the cover or to dismantle the module chassis. Additionally, screws are generally an inexpensive and easy to handle mounting tool.

The advantage to a design with a longitudinal groove in the module bars that points inwards, in which the honeycomb screen can be inserted, is that it creates an electrical conductive connection between the module bars and the honeycomb screen that represents a minor electrical contact resistance even for highest frequencies. A further bonding measure between the honeycomb screen and the module bars can be omitted in this design. The honeycomb screen that is inserted in the module bars can be clamped into the longitudinal groove or glued with conductive adhesive.

Preferably, the lateral frame strips show a U-shaped profile that is open to the inside and receives the honeycomb screen. The U-shaped profile strip forms a straight end of the honeycomb screen and can be produced easily and cost effective. The U-profile has the same function as the longitudinal groove in the module bars and guarantees a good electrical bonding of the honeycomb screen with the surrounding frame. The honeycomb screen can be reliably and durably connected with the module bars, or frame strips respectively, by simple pressing of the U-profile or additional gluing with conductive adhesive.

### BRIEF DESCRIPTION OF THE DRAWINGS

An example of one embodiment of the invention is explained below with the help of the attached drawings. They show:

FIG. 1 a perspective view of a module chassis

FIG. 2 the module chassis of FIG. 1 with lifted upper cover; and

FIG. 2b a detail drawing of the front corner of the upper cover in cross-section.

### DETAILED DESCRIPTION

In the following detailed description, reference is made to the accompanying drawings which form a part hereof, and in which are shown by way of illustration specific embodiments in which the invention may be practiced. These embodiments are described in sufficient detail to enable those skilled in the art to practice the invention, and it is to be understood that other embodiments may be utilized and that structural changes may be made without departing from the scope of the present invention. Therefore, the following detailed description is not to be taken in a limiting sense, and the scope of the present invention is defined by the appended claims and their equivalents.

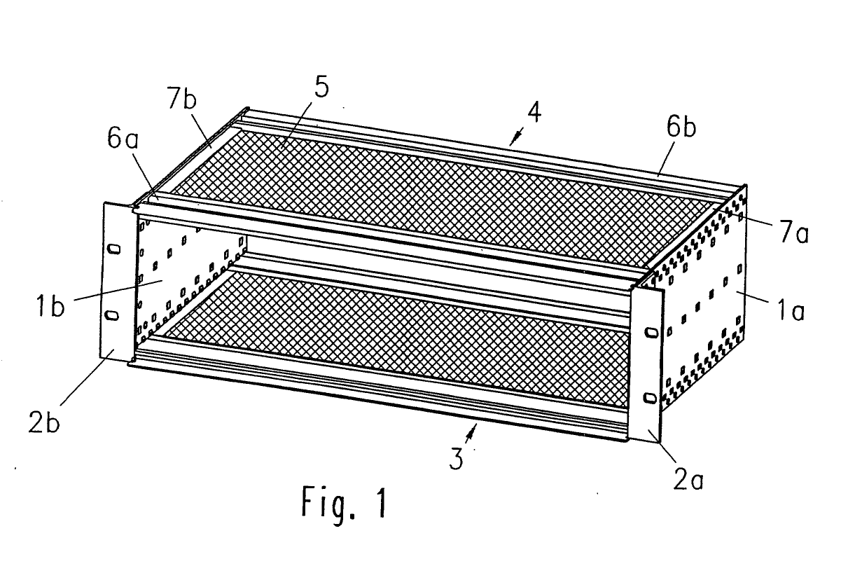

According to FIG. 1, the module chassis has two parallel metallic side walls 1a, 1b, with each one of them having a fastening flange 2a, 2b for the fastening on a frame. The two side walls 1a, 1b are screwed together on their four corners with a lower cover 3 and an upper cover 4.

The covers 3 and 4 each consist of a honeycomb screen 5 that is framed in by a surrounding frame made of metal. The frame consists of a front and rear module bar 6a, 6b and a right and left frame strip 7a, 7b.

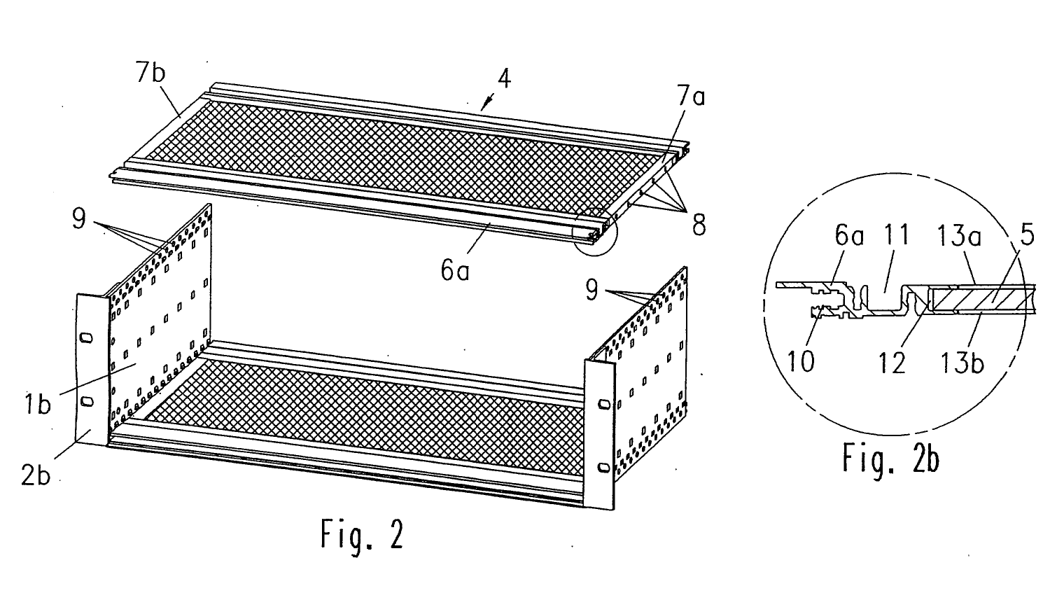

FIG. 2 illustrates in more detail the upper cover 4 loosened from the module chassis. The frame strips 7a and 7b show equally spaced arranged threaded holes 8. The side parts 1a, 1b have with the threaded holes 8 in the frame strips 7a, 7b corresponding drill holes 9, through which (not illustrated) fastening screws can reach through to fasten the side parts 1a, 1b with the frame strips 7a, 7b.

The front right corner of the upper cover 4 is in detail illustrated as cross-section in FIG. 3. The module bar 6a has a typical hollow 10 that is open to the left and in which the partial front panels of modules can be screwed in. Spring elements and sheet metal covers can be fastened in a longitudinal groove 11, which forms the center part of the module bar 6a, just as it is done during the common use of the module bars. The honeycomb screen 5 is inserted in a longitudinal groove 12 that is open to the right. The two legs 13a, 13b, of the U-shaped right frame strip 7a, that enclose the honeycomb screen 5, border on the right side of the module bar 6a.

It is understood that the above description is intended to be illustrative, and not restrictive. Many other embodiments will be apparent to those of skill in the art upon reviewing the above description. The scope of the invention should, therefore, be determined with reference to the appended claims, along with the full scope of equivalents to which such claims are entitled.

What is claimed is:

1. An HF-shielded module chassis for the reception of electronic and/or optical modules, the HF-shielded module chassis comprising:
two side walls;
front and rear module bars that are arranged between the two side walls; and
an upper cover and a lower cover, wherein each of the upper and lower covers includes a honeycomb screen and a surrounding frame made of metal that is electrically conductive connected with the honeycomb screen, the surrounding frame including front and rear frame strips and lateral frame strips, wherein the front and rear module bars each form the front and rear frame strips of the frame, and the lateral frame strips of the frame include means for mounting the lateral frame strips to the side walls.

2. The HF-shielded module chassis of claim 1, wherein the side walls are screwed together with the lateral frame strips.

3. The HF-shielded module chassis of claim 1, wherein the front and rear module bars each have a longitudinal groove that points inwards to hold the honeycomb screen.

4. The HF-shielded module chassis of claim 1, wherein the lateral frame strips each have a U-shaped profile that is open to the inside and embrace the edge of the honeycomb screen.
